(19) United States
(12) Patent Application Publication
(10) Pub. No.: US 2025/0221113 A1
(43) Pub. Date: Jul. 3, 2025

(54) LIGHT SOURCE, LED LAMP, AND COLOR ADJUSTMENT METHOD THEREOF

(71) Applicant: Feit Electric Company, Inc., Pico Rivera, CA (US)

(72) Inventors: Brian Halliwell, Pico Rivera, CA (US); Li CHENGGUI, Xiamen (CN); Cheng QILIANG, Xiamen (CN); Chen PENGSHENG, Xiamen (CN); Wang MINGHONG, Xiamen (CN); Xiao QIUHUA, Xiamen (CN); Yao ZHIJUN, Xiamen (CN)

(21) Appl. No.: 18/970,609

(22) Filed: Dec. 5, 2024

(30) Foreign Application Priority Data
Dec. 28, 2023 (CN) 202311839600.2
Feb. 18, 2024 (CN) 202410180999.6

(51) Int. Cl. H10H 20/851; F21V 9/30; F21V 14/00; F21Y 103/10; F21Y 115/10

(52) U.S. Cl. CPC H10H 20/8512; F21V 9/30; F21V 14/006; H10H 20/8514; F21Y 2103/10; F21Y 2115/10

(57) ABSTRACT

A light source is provided, the source having a substrate; and an LED chip packaged on the substrate, wherein the peak wavelength range of the emitted light of the LED chip is 460-485 nm; the outer surface of the LED chip is covered with a Sr₂SiO₄:Eu phosphor layer or a Sr₂SiO₄:Eu phosphor glue layer. An LED lamp that comprises: a lamp housing; and the blue sky light source is also provided; as is a method for color adjustment of the LED lamp.

### CROSS-REFERENCE TO RELATED APPLICATIONS

The present application claims priority to and the benefit of Chinese Patent Application Serial No. 2023122901288510, filed Dec. 29, 2023; and Chinese Patent Application Serial No. 2024021800690950, filed Feb. 18, 2024; the contents of both of which as are hereby incorporated by reference herein in their entireties. Reference is also made to Chinese Utility Model Ser. No. 2023122901288050, filed Dec. 29, 2023; and Chinese Utility Model Ser. No. 2024021800684000, filed Feb. 18, 2024; the contents of both which as are also hereby incorporated by reference herein, to the extent not contained in the two Chinese patent applications to which priority is expressly claimed.

### BACKGROUND

### Related Field

The present application relates to the field of lighting, and in particular to a light source, an LED lamp and a color adjustment method thereof.

### Related Art

At present, ordinary lighting is mostly used for lighting in enclosed indoor spaces. However, under this lighting method, many enclosed indoor spaces will look claustrophobic, and in this environment, it is difficult for human eyes to see sunlight, which can easily make people feel depressed and irritable, which is not conducive to people's physical and mental health and the improvement of work efficiency.

To address this problem, the lighting industry has proposed a lamp that can simulate sunlight, which is called a blue sky lamp on the market. The light emitted by the blue sky lamp can be similar to sunlight, irradiating the object to be irradiated (such as but not limited to walls or floors) from a specific angle, and forming a lighting spot with light and dark boundaries. At the same time, through the special color scattering effect of the blue sky lamp, it can also present a scene similar to sunlight. In this way, people can feel like they are in a natural environment similar to sunlight, which improves people's comfort with lighting and reduces the impact of negative emotions such as depression and irritability.

At present, in order to achieve the blue sky effect, the light source of the blue sky lamps on the market need to be matched with a special lens to realize the blue sky effect, which requires the height of the lamp body to be increased. This solution affects the appearance and is costly. The installation scenario requires the ceiling space to be at least 30 cm, which limits the usage scenarios and has poor applicability.

### BRIEF SUMMARY

Therefore, in order to solve the above problems, the present invention provides a light source, an LED lamp and a color adjustment method thereof.

To achieve the above purpose, the technical solution provided by the present invention is as follows:

A cyan blue light source comprises a substrate and an LED chip packaged on the substrate, wherein the peak wavelength range of the emitted light of the LED chip is 460-485 nm; the outer surface of the LED chip is covered with a Sr₂SiO₄:Eu phosphor layer or a Sr₂SiO₄:Eu phosphor glue layer.

Furthermore, the outer surface of the LED chip is covered with a Sr₂SiO₄:Eu phosphor layer, and the outer surface of the Sr₂SiO₄:Eu phosphor layer is also covered with a transparent isolation protection layer.

Furthermore, the outer surface of the LED chip is covered with a transparent packaging adhesive layer, and the Sr₂SiO₄:Eu phosphor layer covers the surface of the packaging adhesive layer.

Furthermore, the outer surface of the Sr₂SiO₄:Eu phosphor layer is also covered with a transparent isolation protection layer.

Furthermore, the outer surface of the LED chip is covered with a Sr₂SiO₄:Eu fluorescent glue layer, and the Sr₂SiO₄:Eu fluorescent glue layer is a mixture of Sr₂SiO₄:Eu fluorescent powder and packaging glue in a mass ratio of 1:30-1:50.

An LED lamp comprises a lamp housing and a blue sky light source, wherein the blue sky light source has the blue sky light source described above.

Furthermore, the blue sky lamp also has a twilight blue light source, and the blue sky light source and the twilight blue light source are mixed according to a certain output ratio to obtain at least blue sky mixed light and twilight blue mixed light effects, presenting blue sky effects at different times of the day.

Furthermore, the twilight blue light source includes blue light beads, red light beads and green light beads, wherein the light intensity ratio of the blue light beads, the red light beads and the green light beads is (100±1):(93±1):(99±1).

Furthermore, the LED skylight may be a ceiling lamp having a lamp housing that has a central window located in the center and an annular window located at the bottom periphery of the central window, the light source is arranged in the central window, and the annular window is provided with an illumination light source.

Furthermore, a shading plate, a light guide plate, a diffusion plate and a light-transmitting plate which are stacked in sequence are arranged in the central window, the light-transmitting plate faces the light-emitting surface of the lamp housing, the blue sky light source is arranged on the periphery of the light guide plate, and the lamp beads on the blue sky light source are facing the outer peripheral surface of the light guide plate.

Furthermore, the illumination light source includes a lighting strip and a light-transmitting cover. The lighting strip is arranged on the inner wall of the lamp housing with the light-emitting surface facing inward, and the light-transmitting cover covers the lighting strip. The lighting strip is also provided with a lens capable of changing the light-emitting angle.

Furthermore, the light emitting surfaces of the blue sky lamp body formed by the blue sky light source and the illumination light source located on the periphery are not in the same plane, and the light emitting surface of the illumination light source is 2 mm-20 mm lower than the light emitting surface of the blue sky lamp body; and the lamp beads of the illumination light source are arranged downward, so that the angle of the lighting light emitted by the illumination light source is 20°-100°.

Furthermore, the lamp housing extends downward by 5 mm-20 mm between the central window and the annular window to form a partition, and the lamp beads of the lighting source are mounted on the outer side wall of the partition. The light emitted by the lamp beads of the lighting source is reflected by the lamp housing to the lower light outlet and emitted, and the angle of the lighting source emitted through the lower light outlet is 20°-100°.

A color adjustment method for an LED blue sky lamp adopts the LED blue sky lamp described above; a blue sky blue light source emits blue sky blue light, and a twilight blue light source emits twilight blue light. When the blue sky blue light output accounts for 60%-100% and the twilight blue light output accounts for 0-40%, blue sky blue light is obtained by mixing; when the blue sky blue light output accounts for 0-40% and the twilight blue light output accounts for 60%-100% twilight blue light is obtained by mixing.

The technical solution provided by the present invention has the following beneficial effects: blue sky light source uses an LED chip with a peak wavelength range of 460-485 nm and a Sr₂SiO₄:Eu phosphor layer or Sr₂SiO₄:Eu phosphor glue layer covering the LED chip, so that the blue sky light source can obtain a blue sky light effect. There is no need to use a special lens to match, and there is no need to increase the height of the lamp body, so that the volume of the lamp is effectively reduced, and the cost is effectively reduced; and color adjustment method of the LED blue sky lamp of the present application, when used in conjunction with a white light lighting source, the lighting light source can emit sufficiently bright white light without affecting the effect of the blue sky light source emitting blue sky blue light or twilight blue light.

### BRIEF DESCRIPTION OF THE DRAWINGS

FIG. 1 is a schematic diagram showing the structure of a light source in Example 1.

FIG. 2 is a schematic diagram showing the appearance of the LED lamp in the first embodiment.

FIG. 3 is a second schematic diagram of the appearance of the LED lamp in the first embodiment.

FIG. 4 is a schematic diagram showing the structure of the LED lamp in the first embodiment.

FIG. 5 is a cross-sectional view of the LED lamp in Example 1.

FIG. 6 is an enlarged schematic diagram of the A region in FIG. 5.

FIG. 7 is a schematic diagram showing the structure of a blue sky light source in Embodiment 2.

FIG. 8 is a cross-sectional view of the LED lamp in the second embodiment.

FIG. 9 is an enlarged schematic diagram of area B in FIG. 8.

FIG. 10 is a schematic diagram showing the structure of a blue sky light source in Embodiment 3.

FIG. 11 is a schematic diagram showing the structure decomposition of the LED lamp in the third embodiment.

FIG. 12 is a schematic diagram showing the structural decomposition of the LED lamp in the fourth embodiment.

FIG. 13 is a cross-sectional view of the structure of the LED lamp in the fifth embodiment.

FIG. 14 is a schematic diagram of a portion of the structure shown in FIG. 13.

FIG. 15 is a cross-sectional view of the structure of the LED lamp in the sixth embodiment.

FIG. 16 is a schematic diagram of the partial structure shown in FIG. 15.

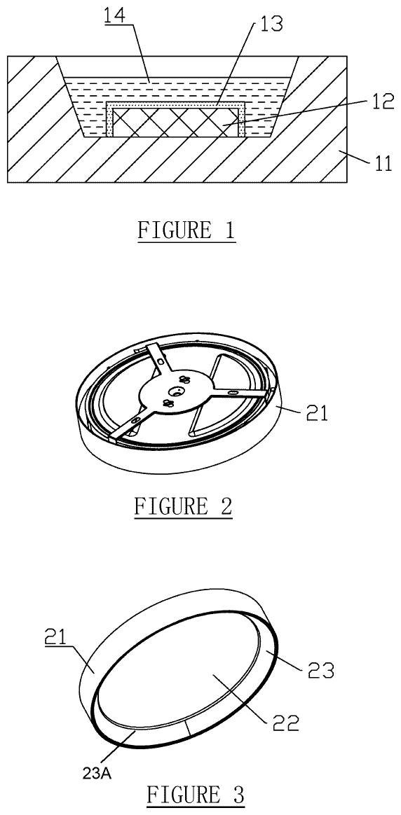

### DETAILED DESCRIPTION

To further illustrate the various embodiments, the present invention provides drawings. These drawings are part of the disclosure of the present invention, which are mainly used to illustrate the embodiments and can be used in conjunction with the relevant descriptions in the specification to explain the operating principles of the embodiments. With reference to these contents, a person of ordinary skill in the art should be able to understand other possible implementations and advantages of the present invention. The components in the figures are not drawn to scale, and similar component symbols are generally used to represent similar components.

The present invention will now be further described with reference to the accompanying drawings and specific implementation methods.

### First Embodiment

Cyan blue light source provided in this embodiment includes a substrate 11 and an LED chip 12 packaged on the substrate 11, wherein the peak wavelength range of the emitted light of the LED chip 12 is 460-485 nm; the outer surface of the LED chip 12 is covered with a Sr₂SiO₄:Eu phosphor layer 13, and specifically, the Sr₂SiO₄:Eu phosphor layer 13 refers to a phosphor layer laid by Sr₂SiO₄:Eu phosphor. Specifically, in this embodiment, the outer surface of the LED chip 12 is covered with a layer of Sr₂SiO₄:Eu phosphor layer, and then a transparent isolation protective layer (defined as a first isolation protective layer 14) is covered on the surface of the Sr₂SiO₄:Eu phosphor layer, and the first isolation protective layer 14 adopts an existing epoxy resin layer or a silicone layer used for packaging, so as to achieve stable packaging. Of course, in other embodiments, the first isolation protective layer 14 may not be provided.

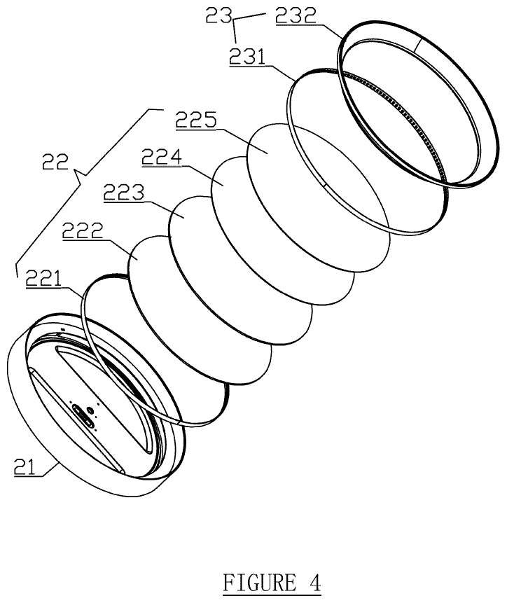

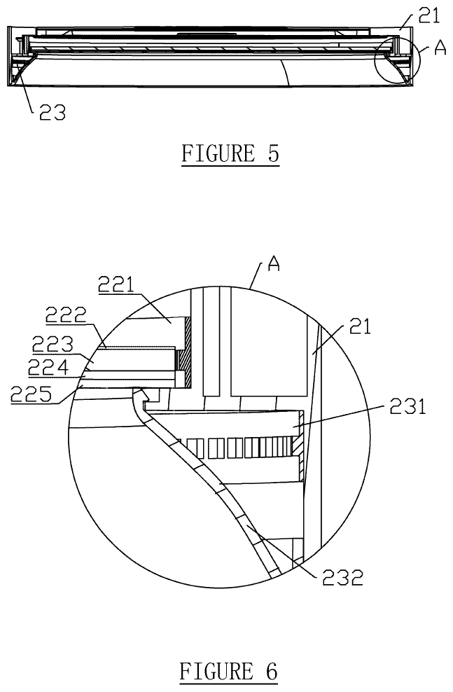

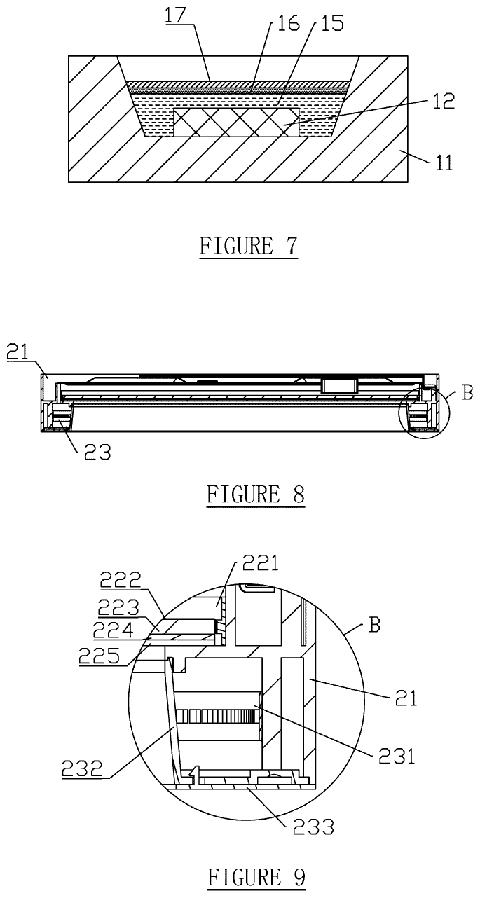

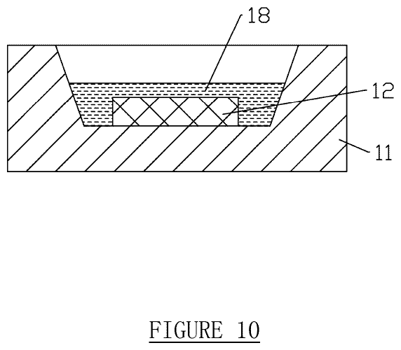

As understood from FIGS. 2 to 6, this embodiment also provides an LED lamp, including a lamp housing 21 and a blue sky light source 221, wherein the blue sky light source 221 has the blue sky blue light source described above. After the blue sky light source is powered on, it works at rated power to obtain a blue sky blue light effect.

Specifically, in this embodiment, the LED lamp is a ceiling lamp, and the lamp housing 21 has a central window located in the center and an annular window 23A located at the bottom periphery of the central window. The blue sky light source 221 is arranged in the central window for main lighting, and the annular window 23A is provided with a lighting light source 23, which mainly plays a decorative and lighting role.

The central window is provided with a shading plate 222, a light guide plate 223, a diffusion plate 224 and a light transmission plate 225 which are stacked in sequence. The light transmission plate 225 faces the light emitting surface of the lamp housing 21. The blue sky light source 221 is arranged on the periphery of the light guide plate 223, and the lamp beads on the blue sky light source 221 face the outer peripheral surface of the light guide plate 223.

The light emitted by the blue sky light source 221 enters the light guide plate 223 through the outer peripheral surface of the light guide plate 223, and then exits from the bottom surface of the light guide plate 223 to the diffuser plate 224, is evenly diffused by the diffuser plate 224, and finally exits through the light-transmitting plate 225. A light shielding plate 222 is disposed on the top of the light guide plate 223, so that the light cannot exit from the top.

Specifically, the blue sky light source 221, the light shielding plate 222, the light guide plate 223, the diffusion plate 224 and the light transmitting plate 225 constitute the blue sky lamp body 22.

The lighting source 23 includes a lighting strip 231 and a light-transmitting cover 232. The lighting strip 231 is arranged on the inner wall of the lamp housing 21 and the light-emitting surface is arranged inward, and the light-transmitting cover 232 covers the lighting strip 231. Specifically, the lighting strip 231 can adopt an existing white light strip for lighting. etc., mainly for decoration and lighting. Specifically, the light-transmitting surface of the light-transmitting cover 232 corresponding to the lighting strip 231 is a downward inclined surface, which can better illuminate downward.

Of course, in other embodiments, the illumination light source 23 may not be provided. At the same time, the LED skylight can also be a panel light, a ceiling light, or the like. Thus, by adopting the solution of the present application, there is no need to use a dedicated lens to obtain the blue light of the blue sky, and there is no need to increase the height of the lamp body, so that the volume of the lamp is effectively reduced, and the cost is effectively reduced.

### Second Embodiment

Cyan blue light source provided in this embodiment includes a substrate 11 and an LED chip 12 packaged on the substrate 11, wherein the peak wavelength range of the emitted light of the LED chip 12 is 460-485 nm; the outer surface of the LED chip 12 is covered with a Sr₂SiO₄:Eu phosphor layer 16, and specifically, the Sr₂SiO₄:Eu phosphor layer 16 refers to a phosphor layer laid by Sr₂SiO₄:Eu phosphor. Specifically, in this embodiment, the outer surface of the LED chip 12 is first covered with a layer of packaging glue layer 15, and the Sr₂SiO₄:Eu phosphor layer 16 is covered on the surface of the packaging glue layer 15. In this way, a remote phosphor structure is obtained, so that the Sr₂SiO₄:Eu phosphor layer 16 is far away from the LED chip 12, and the heat emitted by the LED chip 12 is prevented from affecting the Sr₂SiO₄:Eu phosphor layer 16.

Meanwhile, more preferably, the outer surface of the Sr₂SiO₄:Eu phosphor layer 16 is also covered with a transparent isolation protection layer (defined as the second isolation protection layer 17) to achieve isolation protection for the Sr₂SiO₄:Eu phosphor layer 16. Specifically, the encapsulation glue layer 15 and the second isolation protection layer 17 can both be epoxy resin layers or silicone layers used in existing encapsulation.

This embodiment also provides an LED blue sky lamp. Specifically, the LED blue sky lamp has a structure roughly the same as that of the first embodiment and is also a ceiling lamp. The difference is that: as shown in FIGS. 8 and 9, the blue sky light source 221 has the blue sky blue light source described in the second embodiment, and at the same time, the blue sky light source 221 also has a twilight blue light source. Specifically, in this embodiment, the twilight blue light source includes blue light beads, red light beads and green light beads, wherein the light intensity ratio of the blue light beads, the red light beads and the green light beads is (100±1):(93±1):(99±1). If the twilight blue light source is adjusted to 15%-20% of its rated power, twilight blue light is obtained. Of course, in other embodiments, the twilight blue light source is not limited to this.

The inclination of the light-transmitting surface of the light strip 231 corresponding to the light cover 232 of the lighting light source 23 is smaller than that of the structure of the first embodiment, and the lighting light source 23 also includes a shading ring 233, which is arranged at the bottom of the light cover 232 to fix the light cover 232 on the lamp housing 21. At the same time, the shading ring 233 can block the light emitted downward from the lighting strip 231, so that the light of the lighting strip 231 is more emitted horizontally toward the center, thereby cooperating with the emitted light of the blue sky light source 221 to obtain a better lighting effect.

The present embodiment also provides a color adjustment method for an LED blue sky lamp, using the LED blue sky lamp described in the present embodiment; the blue sky blue light source emits blue sky blue light, and the twilight blue light source emits twilight blue light. When the blue sky blue light output accounts for 60%-100% and the twilight blue light output accounts for 0-40%, blue sky blue mixed light is obtained by mixing; when the blue sky blue light output accounts for 0-40% and the twilight blue light output accounts for 60%-100%, twilight blue mixed light is obtained by mixing.

This embodiment obtains cyan blue mixed light or twilight blue mixed light by mixing light. When combined with the white light illumination light source 23, it can enable the illumination light source 23 to emit sufficiently bright white light without affecting the effect of the cyan blue light source 22 emitting cyan blue light or twilight blue light.

### Third Embodiment

The light source provided in this embodiment includes a substrate 11 and an LED chip 12 packaged on the substrate 11, wherein the peak wavelength range of the emitted light of the LED chip 12 is 460-485 nm; the outer surface of the LED chip 12 is covered with a Sr₂SiO₄:Eu fluorescent glue layer 18, specifically, the Sr₂SiO₄:Eu fluorescent glue layer 18 refers to a mixture of Sr₂SiO₄:Eu fluorescent powder and packaging glue in proportion.

Specifically, as one preferred solution, in this embodiment, the Sr₂SiO₄:Eu fluorescent glue layer 18 is formed by mixing Sr₂SiO₄:Eu fluorescent powder and packaging glue in a mass ratio of 1:30-1:50. Specifically, the packaging glue is epoxy resin or silica gel.

The LED lamp provided in this embodiment has a substantially similar structure to that of the second embodiment, except that in this embodiment, the blue sky light source 221 has the blue sky light source described in the third embodiment.

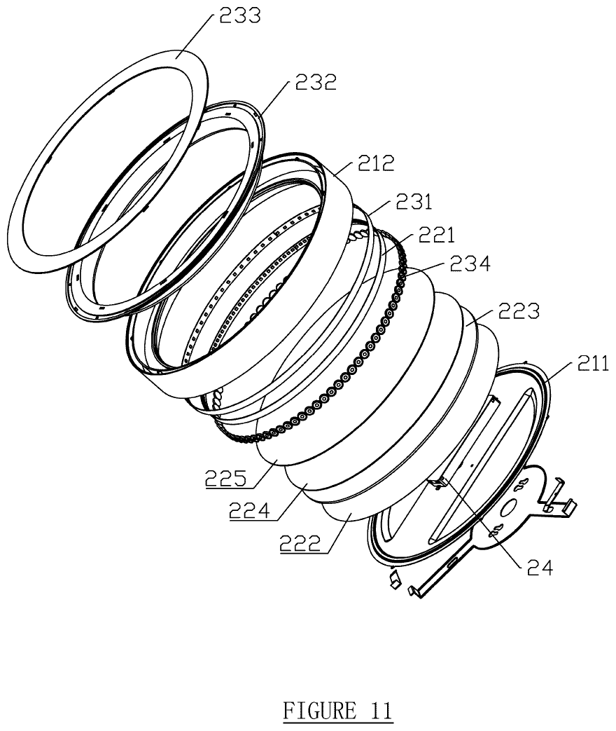

Continuing to refer to FIG. 11, the lamp housing 21 is composed of a back plate 211 and a lamp frame 212. The back plate 211 is equipped with a driving power source 24; that is, the driving power source 24 is also integrated into the entire lamp.

At the same time, the lighting strip 231 is also equipped with a lens 234 that can change the light output angle. By adding the lens 234, the light output angle of the lighting light source 23 can be adjusted according to actual needs, and the influence of the main lighting light on the blue sky light source can be well handled. The blue sky light and the lighting light can be used at the same time without affecting the luminous effect of the blue sky light source 221.

Specifically, the lens 234 capable of changing the light output angle is an existing lens, such as an LED lens disclosed in CN201348192Y. This lens 234 cooperates with the LED chip, has a small size, and is arranged on the lighting strip 231. There is sufficient layout space, and it will not affect the layout of the entire lamp.

Specifically, the lens 234 can be packaged together with the LED chip when the LED lamp bead is packaged, that is, the lens is included on the lamp bead of the lighting strip 231, or it can be added on the surface of the lamp bead of the lighting strip 231, that is, there is no lens 234 on the lamp bead, and the lens 234 is subsequently installed on the lighting strip 231.

### Fourth Embodiment

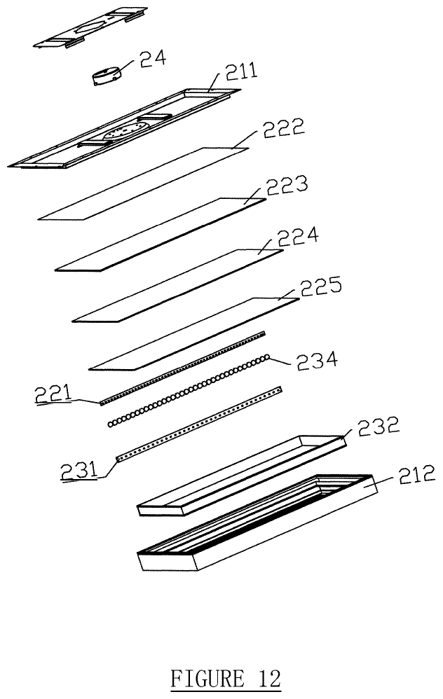

The LED lamp provided in this embodiment has substantially the same structure as that of the third embodiment, except that: as shown in FIG. 12, the LED blue sky lamp is a square ceiling lamp, and the back panel 211, the lamp frame 212, the shading plate 222, the light guide plate 223, the diffusion plate 224, and the light-transmitting plate 225 are all square structures.

### Fifth Embodiment

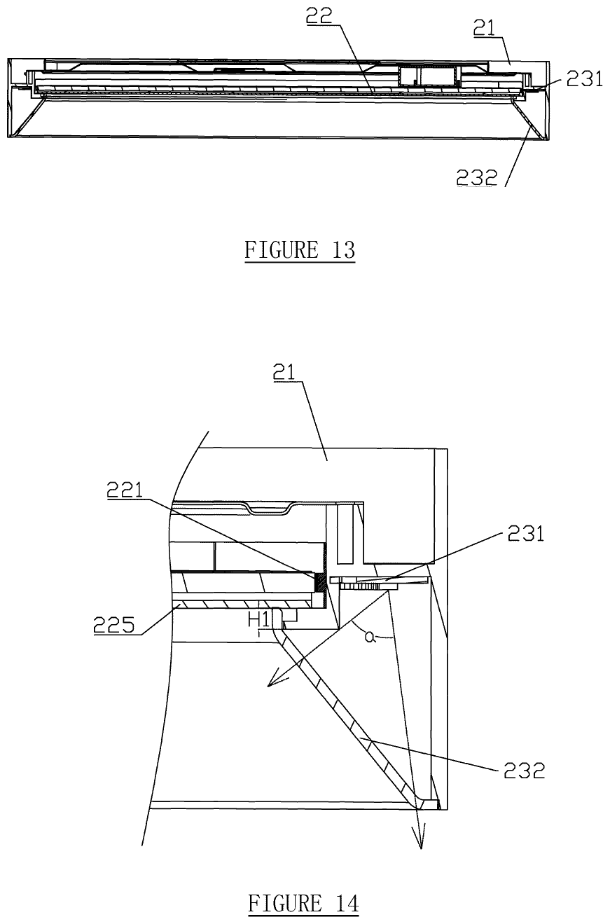

The LED lamp provided in this embodiment has a structure substantially the same as that of the fourth embodiment, except that: as shown in FIGS. 13 and 14, the blue sky lamp body 22 composed of the blue sky light source 221 and the light emitting surface of the illumination light source 23 located at the periphery are not in the same plane, the light emitting surface of the blue sky lamp body 22 is the bottom surface of the light-transmitting plate 225, and the light emitting surface of the illumination light source 23 is the light-transmitting cover 232; the light emitting surface of the illumination light source 23 is 2 mm-20 mm lower than the light emitting surface of the blue sky lamp body 22; that is, as shown in FIG. 14, the sinking height Hl of the light emitting surface (light-transmitting cover 232) of the illumination light source 23 compared to the bottom surface of the light-transmitting plate 225 is 2 mm-20 mm. In addition, the lamp beads of the illumination light source 23 (i.e., the lamp beads of the illumination light strip 231) are arranged downward, so that the illumination light emitted by the illumination light source 23 is irradiated downward, and the angle a emitted from the light-transmitting cover 232 is 20°-100°. In this way, the white light emitted by the illumination light source 23 when it is turned on does not affect the light emitted by the blue sky lamp body 22.

### Sixth Embodiment

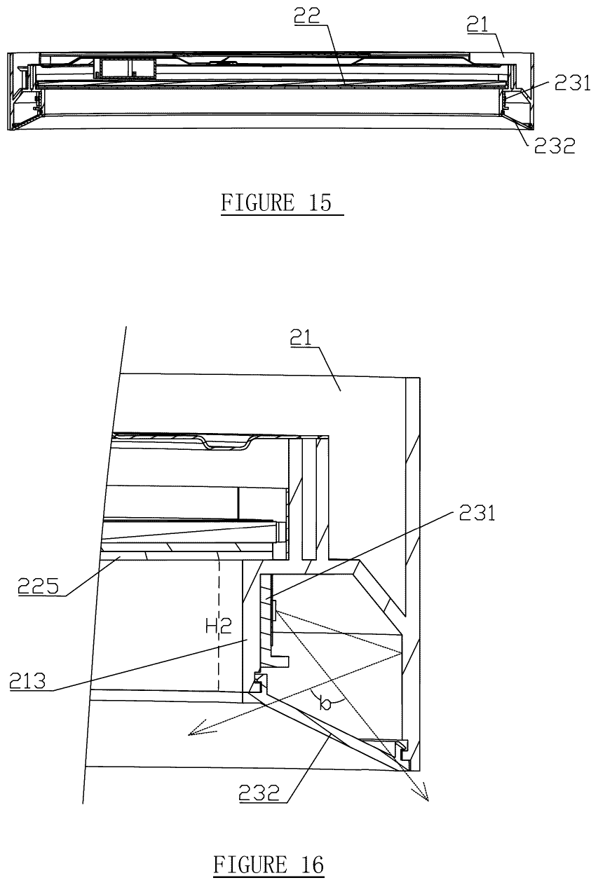

The LED lamp provided in this embodiment has a structure substantially the same as that of the fourth embodiment, except that: as shown in FIG. 15 and FIG. 16, the lamp housing 21 extends downward by 5 mm-20 mm between the central window and the annular window to form a partition 213, that is, as shown in FIG. 16, the lower edge height H2 of the partition 213 is 5 mm-20 mm. The lamp beads of the lighting source 23 (that is, the lamp beads of the lighting strip 231) are mounted on the outer side wall of the partition 213. As shown in FIG. 16, the pair of light rays emitted by the lamp beads of the lighting source 23 is reflected by the lamp housing 21 to the lower light outlet, that is, emitted from the light-transmitting cover 232, and the angle b between the pair of light rays emitted through the lower light outlet is 20°-100°. In this way, the white light emitted when the lighting source 23 is turned on does not affect the light emitted by the lamp body 22.

### CONCLUSION

Although the present invention has been specifically shown and described in conjunction with the preferred embodiments, it should be understood by those skilled in the art that various changes may be made to the present invention in form and details without departing from the spirit and scope of the present invention as defined by the appended claims, all of which are within the scope of protection of the present invention.

1. A light source, comprising:
a substrate; and
an LED chip packaged on the substrate,
wherein:
the peak wavelength range of the emitted light of the LED chip is 460-485 nm; and
the outer surface of the LED chip includes a Sr₂SiO₄:Eu phosphor layer.

2. The light source according to claim 1, wherein the light source is a cyan blue light source.

3. The light source according to claim 1, wherein the Sr₂SiO₄:Eu phosphor layer is a Sr₂SiO₄:Eu phosphor glue layer.

4. The light source according to claim 3, wherein an outer surface of the Sr₂SiO₄:Eu phosphor layer includes a transparent isolation protection layer.

5. The light source according to claim 1, wherein the outer surface of the LED chip includes a transparent packaging adhesive layer, and the Sr₂SiO₄:Eu phosphor layer covers the surface of the packaging adhesive layer.

6. The light source according to claim 1, wherein the outer surface of the LED chip includes a Sr₂SiO₄:Eu fluorescent glue layer.

7. The light source according to claim 6, wherein the Sr₂SiO₄:Eu fluorescent glue layer is a mixture of Sr₂SiO₄:Eu fluorescent powder and packaging glue in a mass ratio of 1:30-1:50.

8. An LED lamp that comprises:
a lamp housing; and
a blue sky light source,
wherein the blue sky light source comprises:
a substrate; and
an LED chip packaged on the substrate,
wherein: the peak wavelength range of the emitted light of the LED chip is 460-485 nm; the outer surface of the LED chip is covered with a Sr₂SiO₄:Eu phosphor layer or a Sr₂SiO₄:Eu phosphor glue layer.

9. The LED lamp according to claim 8, further comprising a twilight blue light source, wherein the blue sky light source and the twilight blue light source are mixed according to a predetermined output ratio to obtain at least blue sky blue mixed light and twilight blue mixed light effects.

10. The LED lamp according to claim 9, wherein the predetermined output ratio is a 60/40 ratio.

11. The LED lamp according to claim 8, wherein the twilight blue light source includes blue light beads, red light beads, and green light beads.

12. The LED lamp according to claim 11, wherein the light intensity ratio of the blue light beads, the red light beads, and the green light beads is (100±1):(93±1):(99±1).

13. The LED lamp according to claim 12, wherein: the lamp is a ceiling lamp, the lamp housing has a central window located in the center and an annular window located at the bottom periphery of the central window, at least one of the light sources is arranged in the central window, and an illumination light source is arranged in the annular window.

14. The LED lamp according to claim 12, wherein: a shading plate, a light guide plate, a diffusion plate and a light-transmitting plate which are stacked in sequence are arranged in the central window, the light-transmitting plate faces the light-emitting surface of the lamp housing, the blue sky light source is arranged on the periphery of the light guide plate, and the lamp beads on the blue sky light source are facing the outer peripheral surface of the light guide plate.

15. The LED lamp according to claim 12, wherein: the lighting light source includes a lighting light strip and a light-transmitting cover, the lighting light strip is arranged on the inner wall of the lamp housing with the light-emitting surface facing inward, and the light-transmitting cover covers the lighting light strip.

16. The LED lamp according to claim 15, wherein the lighting light strip is provided with a lens capable of changing the light-emitting angle.

17. The LED lamp according to claim 12, wherein: the sky lamp body is composed of the blue sky light source and the light-emitting surface of the peripheral illumination light source are not on the same plane, and the light-emitting surface of the illumination light source is larger than the blue sky light source.

18. The LED lamp according to claim 17, wherein the light-emitting surface of the lamp body is 2 mm-20 mm lower; and the lamp beads of the lighting source are set downwards, so that the angle of the illuminating light emitted by the lighting source is 20°-100°.

19. The LED lamp according to claim 12, wherein: the lamp housing extends downward by 5 mm-20 mm between the central window and the annular window to form a partition, and the lamp beads of the lighting source are assembled on the partition.

20. The LED lamp according to claim 19, wherein, on the outer side wall of the lamp, the light emitted by the lamp beads of the lighting source is reflected by the lamp housing to the light outlet below, and the angle at which the illumination light source is emitted through the light outlet below is 20°-100°.

21. A method for color adjustment of the lamp of claim 9, the method comprising the steps of:
when the blue sky blue light output accounts for 60%-100% and the twilight blue light output accounts for 0-40%, generating the blue sky light mixed light by mixing the blue sky blue light emitted by the blue sky blue light source, and the twilight blue light emitted by the twilight blue light source, and
when the blue sky blue light output accounts for 0-40% and the twilight blue light output accounts for 60%-100%, generating twilight blue mixed light by mixing the blue sky light mixed light by mixing the blue sky blue light emitted by the blue sky blue light source, and the twilight blue light emitted by the twilight blue light source.
